(19) United States
(12) Patent Application Publication
(10) Pub. No.: US 2004/0151032 A1
(43) Pub. Date: Aug. 5, 2004

(54) High speed and low noise output buffer

(76) Inventors: Yan Polansky, Ramat-Gan (IL); Eduardo Maayan, Kfar Saba (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/353,957

(22) Filed: Jan. 30, 2003

(51) Int. Cl. G11C 7/00; G11C 5/00

(52) U.S. Cl. 365/189.05; 365/189.11

(57) ABSTRACT

Output buffer circuitry and a waveform for driving either a pull-up or pull-down transistor in the output stage thereof are described. The waveform may include a first segment that brings the transistor close to or at its turn-on condition substantially upon application of the waveform to the gate of the transistor, and may include a second segment that monotonically changes over an-operative range. A path of the output buffer may include a data input stage configured to receive a signal thereat, an output stage transistor having a gate terminal, a current source, and a switch responsive to the logic state of the signal received at the data input stage. The switch selectively may connect the current source to the gate terminal of the output stage transistor, wherein the current source may apply a drive current to the gate terminal to convey the data output from the output stage transistor.

### FIELD OF THE INVENTION

The present invention relates to an interface circuit for an integrated circuit chip and more particularly to an output buffer arrangement having a short switching time and a low switching noise.

### BACKGROUND OF TH INVENTION

Output buffers are employed in a variety of memory devices, such as EPROM (electrically programmable read-only memory), DRAM (dynamic random access memory), and other flash memory applications. A common application for output buffers is the transfer of memory data signals from a sense amplifier associated with a memory array to external circuitry. In order to reduce the die cost, memory devices usually have power networks with limited performance. For example, these power networks may have a relatively large impedance and poor step response. However, memory devices that employ output buffers generally require high speed and low noise operation. If fast switching output buffers are used, switching noise may be created due to the limited performance characteristics of the power networks. The noise may be significant enough to degrade the device performance or even cause functional failures.

A low noise output buffer would therefore be desirable, especially for memory array applications in which multiple, parallel output buffers are used to transfer memory data signals as output signals.

High speed, that is, the ability to rapidly charge and discharge the output load current in a short period of time, is another desirable characteristic of output buffers, which may improve overall performance of the memory device. However, high speed may result in large voltage fluctuations on the supply lines, and hence switching noise injected into the device. More particularly, charging due to the activation of a pull-up transistor or discharging due to the activation of a pull-down transistor usually causes a decaying oscillatory noise on the power supply leads. The oscillatory amplitude and decay time characteristics depend on the current change rate, and on the electrical response of the power network on-and-off die. The speed of the output buffer, which must drive relatively large capacitances (30-100 pF), is often limited by noise consideration.

The worst-case scenario for introducing noise (that is, conditions which are likely to generate switching noise, e.g., by causing large driving currents) is usually when the local voltage supply is high, the transistors are “fast” (in term of the process parameters, e.g., shorter than typical channel lengths), and the environmental conditions are “fast” (e.g., low temperature). On the other hand, the worst-case scenario for speed (that is, conditions which impair the ability to rapidly charge and discharge the output load current in a short period of time) is usually when operating at low supply voltage, the transistors are “slow” (e.g., process which resulted in longer than typical channel lengths), and at a high temperature.

Accordingly, although attaining high speed and maintaining low noise are both desirable goals, they are conflicting goals and present a problem in designing an output buffer. The speed penalty when optimizing the output buffer noise performance or the noise penalty when optimizing the output buffer speed may be huge.

It is therefore desirable to provide the output buffer with either some controlling means that slow down the buffer at fast conditions or speed it up at slow conditions.

One approach to controlling noise is to impose a smoothing function such as an RC circuit in the data signal path upstream of the output pull-down and pull-up transistors. An RC circuit causes the voltage at the gate of such transistors to increase gradually and thereby control the rate of change of current in the output circuit. This approach reduces switching noise, but sacrifices output buffer speed.

### SUMMARY OF THE INVENTION

The present invention seeks to provide methods and circuitry to reduce or minimize noise at a given output buffer delay (speed), or to reduce or minimize the output buffer delay (speed) for a given noise level. In accordance with an embodiment of the present invention a driving waveform and circuitry are provided which cause a constant rate of change in current in the output buffer's load circuit while the active devices are saturated.

In accordance with an embodiment of the present invention a waveform is described for use in driving either a pull-up or pull-down transistor in the output stage of an output buffer. The waveform may include a first segment that brings the transistor close to or at its turn-on condition substantially upon application of the waveform to the gate of the transistor, and includes a second segment that may monotonically increase over an operative range.

In accordance with another embodiment of the present invention, a path is provided in an output buffer circuit for either pulling-up a data output to logic HIGH or for pulling-down the data output to logic LOW. The path may include a data input stage configured to receive a signal thereat, an output stage transistor having a gate terminal, a current source, and a switch responsive to the logic state of the signal received at the data input stage. The switch may selectively connect the current source to the gate terminal of the output stage transistor such that the current source applies a drive current to the gate terminal to convey the data output from the output stage transistor.

In accordance with yet another embodiment of the present invention, an output buffer circuit is provided which includes a data input configured to receive a signal thereat, a data output configured to provide a logic value thereat as a function of the signal received at the data input, first and second signal paths, a current source available to supply current to each of the first and second signal paths having respective output stage transistors, and a switch in each of the first and second signal paths, the switch being responsive to the logic state of the signal received at the data input stage to selectively connect the current source to the gate terminal of a respective output stage transistor, wherein the current source applies a drive current to the gate terminal.

Preferably, the first signal path extends between the data input and the data output and selectively provides a logic HIGH to the data output whereas the second signal path extends between the data input and the data output and selectively provides a logic LOW to the data output. The signal paths preferably include respective first and second output stage transistors having respective drain terminals connected to the data output and a gate terminal connected to that stage.

### BRIEF DESCRIPTION OF THE DRAWINGS

The present invention will be understood and appreciated more fully from the following detailed description taken in conjunction with the drawings in which:

FIG. 1 is a schematic circuit illustrating components of an output buffer in accordance with an embodiment of the present invention;

FIG. 2 is a state diagram of the output buffer of FIG. 1, showing the states of several switches (e.g., transistors) that may be used to implement the circuit of FIG. 1 for stable states and for data transitions;

FIG. 3 is a transistor diagram of the output buffer of FIG. 1, in accordance with an embodiment of the invention;

FIG. 4 is a plot of a preferred driving voltage for an output stage transistor of an output buffer in accordance with an embodiment of the invention;

FIG. 5 is a plot of voltage versus time as a function of driving current (Io1, Io2, Io3) for an output stage of a family of driving current sources in accordance with an embodiment of the invention; and

FIG. 6 is a plot of the switching characteristics (voltage versus time) of an output buffer for the family of driving current sources in accordance with an embodiment of the invention when driven by the current source curves of FIG. 5.

### DETAILED DESCRIPTION OF CERTAIN PREFERRED EMBODIMENTS

In accordance with an embodiment of the present invention, an output buffer circuit is provided based on the “velocity saturation” mode of operation of NMOS or PMOS (n-channel or p-channel complementary metal oxide semiconductor) transistors.

In order to better understand the operation of the output buffer circuit, a brief explanation of the physics of devices in “velocity saturation mode” is now provided. As channel lengths are shortened, the physical mechanism of “velocity saturation” comes into play, as understood by those skilled in the art. Velocity saturation effects are manifested as a reduction in drain-source current for a given change in gate-source voltage. More particularly, an NMOS device has its current proportional to k/2(Vgs−Vt)^{α}, where α≈2 if the device is not subject to velocity saturation, and α≈1 if the device is subject to velocity saturation.

In short channel transistors that are subject to velocity saturation effects, in order to have the transistor's Ids current change constant with time (dIds/dt=constant), the Vgs voltage drop between gate and source of the transistor, should linearly change with time. This means that Vgs must satisfy the relationship Vgs=A·t, where A is a constant and t is time.

The present invention seeks to provide output buffer circuit arrangements having a driving waveform applied to the pull-up and pull-down transistors, which causes a constant rate of change in the current seen in the output path to reduce or minimize noise The waveform provides a desired characteristic while the pull-up or pull-down transistors of the output stage of the output buffer are in velocity saturation mode, namely, the operating time that dominates the speed characteristic of the output buffer.

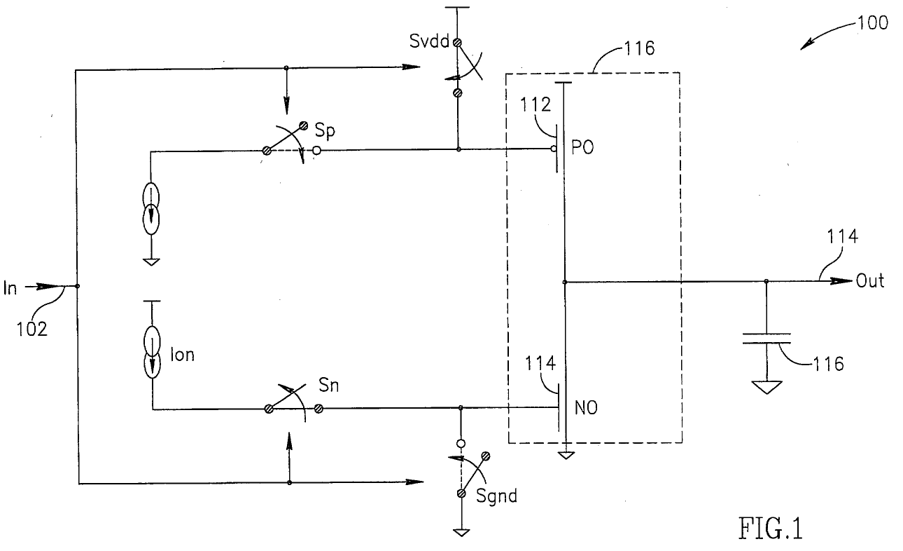

Reference is now made to FIG. 1, which is a schematic circuit illustrating components of an output buffer circuit 100, in accordance with an embodiment of the present invention.

Output buffer circuit 100 may include a signal input node 102, a signal output node 104, and circuitry therebetween to transfer data to a load capacitance 106 at an optimally low noise level for a given output buffer switching speed. The circuit 100 may implement a non-inverting output buffer, that is, one that transfers a logic high signal at its input 102 to its output 104, and transfers a logic low signal at its input to its output. However, the present invention is not limited to this application, and the invention also applies to inverting output buffer circuit designs, in which a logic high signal at the input 102 causes a logic low signal to appear at the output 104, and a logic low signal at the input causes a logic high signal to appear at the output.

Typically, data received at the input 102 of the output buffer circuit 100 is sourced by an on-die circuit (not shown), e.g., a sense amplifier associated with a memory array. The data at the output 104 is ordinarily provided to a load that is not on-die (shown schematically as the capacitance 106), such as the capacitance of a circuit board which is generally in the range of 30-100 pF.

The output buffer circuit 100 may include a pull-up transistor 112 connected between a non-zero voltage source VDD and the output node 104. Preferably, the pull-up transistor is a PMOS device. The output buffer circuit 100 may also include a pull-down transistor 114 connected between ground potential GND and the output node 104. Preferably, the pull-down transistor is an NMOS device. The pull-up and pull-down transistors together comprise an output stage 116 that is driven by signals that cause only one of the two transistors 112 or 114 to be in a conductive state at any one time. The output stage may further comprise additional elements that are necessary for proper functionality, quality or reliability although they do not play a significant role in determining the circuit noise and speed performance (e.g., series resistors connected to the gates of transistors 112 and 114 may be required for electrostatic discharge protection).

In a conventional manner, when the pull-up transistor is conducting, the output buffer circuit 100 transfers a logic high signal to the output node 104 (from voltage source VDD) and the pull-down transistor is preferably in a non-conducting state such that there is no signal path to ground. Similarly, when the pull-down transistor is conducting, the output buffer circuit 100 transfers a logic low signal to the output node 104 (from ground potential GND) and the pull-up transistor is preferably in a non-conducting state such that there is no signal path to VDD.

In accordance with an embodiment of the present invention, a low noise level may be achieved during output toggling by driving the conducting transistor gate at the output stage 116 with a constant current source, while the other transistor in the output stage 116 is non-conducting. A constant current driving the conducting output transistor may ensure that if this transistor operates at a velocity saturation mode then the change in the output current over time (i.e., its first time derivative) is a constant. Consequently, by driving the output stage 116 with a constant current, the noise level in the device may be constant and controllable.

A constant current may be provided to each transistor in the output stage 116 in various ways. As an example, a constant current generator may be used as the input current to current mirror circuits. In a preferred embodiment, this current mirror comprises a first current mirror section in the pull-up path and a second current mirror section in the pull-down path. The first current mirror may be active during the output buffer's pull-up period and may source a current I_{O}_{_{—}}_{P}, whereas the second current mirror may be active during the output buffer's pull-down period and may source a current I_{O}_{_{—}}_{N}. A switch in the pull-up path (S_{P}) and a switch in the pull-down path (S_{N}) are schematically illustrated in FIG. 1, and may be provided to control the timing and duration that the current sources are provided to the gate terminals of the transistors in the output stage 116. Only one of the switches S_{P}, S_{N} is preferably switched to a closed state at any one time, as a response to the input signal 102. However, during data transitions (changes from logic low or high to the opposite logic state), disable circuitry included in each of the pull-up and pull-down paths may force a respective one of the pull-up and pull-down transistors to a non-conducting state by connecting their respective gates to VDD (via switch S_{VDD} in the case of a PMOS pull-up transistor) and GND (via switch S_{GND} in the case of an NMOS pull-down transistor).

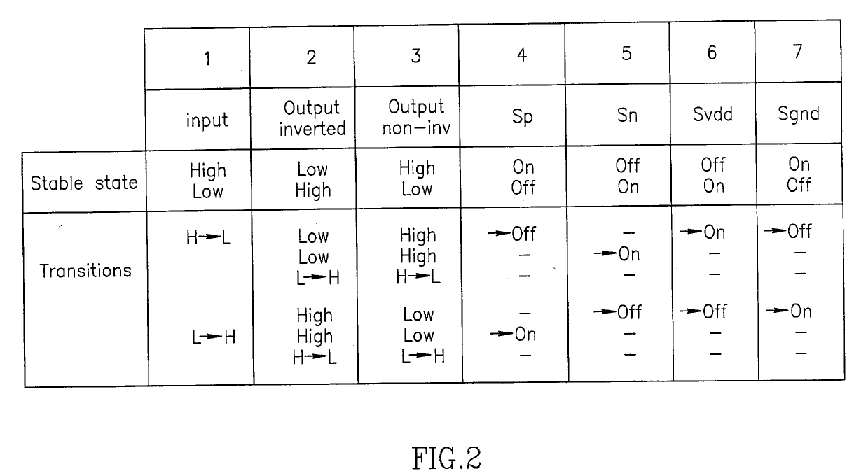

Reference is now made to FIG. 2, which shows a state diagram depicting the states of several switches (e.g., transistors) that may be used to implement the circuit of FIG. 1 for both stable states and for data transitions. The state diagram includes seven columns of data. The first column represents the signal values at the input node 102, either logic low (“LOW”) or logic high (“HIGH”). These binary values may be determined in a conventional manner by gauging an incoming signal as being above or below a threshold value. The output buffer circuit 100 described herein may be non-inverting, and so the description follows with reference to the output listed in column 3; the column 2 output data is included for completeness. Column 3 shows the value at the output node 104 for a given input. Thus, the non-inverting output buffer 100 having a HIGH signal at its input has a HIGH signal at its output and the same output buffer having a LOW signal at its input has a LOW signal at its output. Columns 4 and 5 illustrate the states of the switches S_{P}, S_{N}, for the non-inverting output buffer case. The states of these switches are mutually exclusive whenever the output buffer is in a stable state (as shown in the first two rows of FIG. 2). Columns 6 and 7 illustrate the state of the switches S_{VDD}, S_{GND} for the non-inverting output buffer case, and these switches are also in mutually exclusive positions. By “mutually exclusive,” it is meant that if one is “off” the other is “on.” Also, the term “off” refers to an open switch or a transistor in a mode which does not permit conduction between its terminals (its source and drain terminals in case of an MOS transistor) whereas the term “on” refers to a closed switch or a transistor which permits conduction between its terminals.

With further reference to FIG. 2, it may be appreciated that when the non-inverting output buffer 100 has a stable logic HIGH signal at its input (see column 1), its output node 104 has a logic HIGH signal (column 3), switch S_{P} provides the current source I_{O}_{_{—}}_{P} to the pull-up PMOS transistor 112 while switch S_{N} is off and isolates the current source N from the gate of the pull-down NMOS transistor 114, switch S_{VDD} is off thereby enabling the pull-up transistor to operate whereas S_{D} is on thereby disabling the pull-down transistor.

Similarly, when the when the non-inverting output buffer 100 has a logic LOW signal at its input (see column 1), its output node 104 has a logic LOW signal (column 3), switch S_{P} isolates the current source I_{O}_{_{—}}_{P} from the pull-up PMOS transistor 112 while switch S_{N} provides the current source I_{O}_{_{—}}_{N} to the gate of the pull-down NMOS transistor 114, switch S_{VDD} is on thereby disabling the pull-up transistor whereas S_{GND} is off thereby enabling the pull-down transistor to operate. This is the state depicted in FIG. 1.

FIG. 2 also illustrates the data transitions from HIGH to LOW and from LOW to HIGH as may be seen at the input node 102 of the output buffer. In the case of an output transition from HIGH to LOW, the output node 104 initially remains at logic HIGH while the switches S_{P}, S_{VDD} and S_{GND} switch from one state to the other. Only after these switches change states, does switch S_{N} close and provide the current source I_{O}_{_{—}}_{N} to the pull-down transistor. Shortly thereafter, the current source drives the pull-down transistor 114 into conduction, thereby discharging the load capacitor 106 to ground potential through the path to ground created by the conducting pull-down transistor 114. As the capacitor 106 discharges, the output node 104 goes to logic LOW. Once switch S_{N} has closed, the switches are in a stable state for a LOW input and a LOW output (as seen in row 2 for the non-inverted output case). The sequence of switching ON or OFF the switches S_{N}, S_{P}, S_{VDD} and S_{GND} in FIG. 1 may prevent temporary current paths that waste power and generate unnecessary noise.

Analogously, in the case of an output transition from LOW to HIGH, the output node 104 initially may remain at logic LOW while the switches S_{N}, S_{VDD} and S_{GND} switch from one state to the other. Again, only after these switches change states, does switch S_{P} close and provide the current source I_{O}_{_{—}}_{P} to the pull-up transistor. Shortly thereafter, the current source drives the pull-up transistor 112 into conduction, thereby charging the load capacitor 106 to VDD. As the capacitor 106 charges, the output node 104 goes to logic HIGH. Once switch S_{P} has closed, the switches are in a stable state for a HIGH input and a HIGH output (see row 1 for the non-inverted output case).

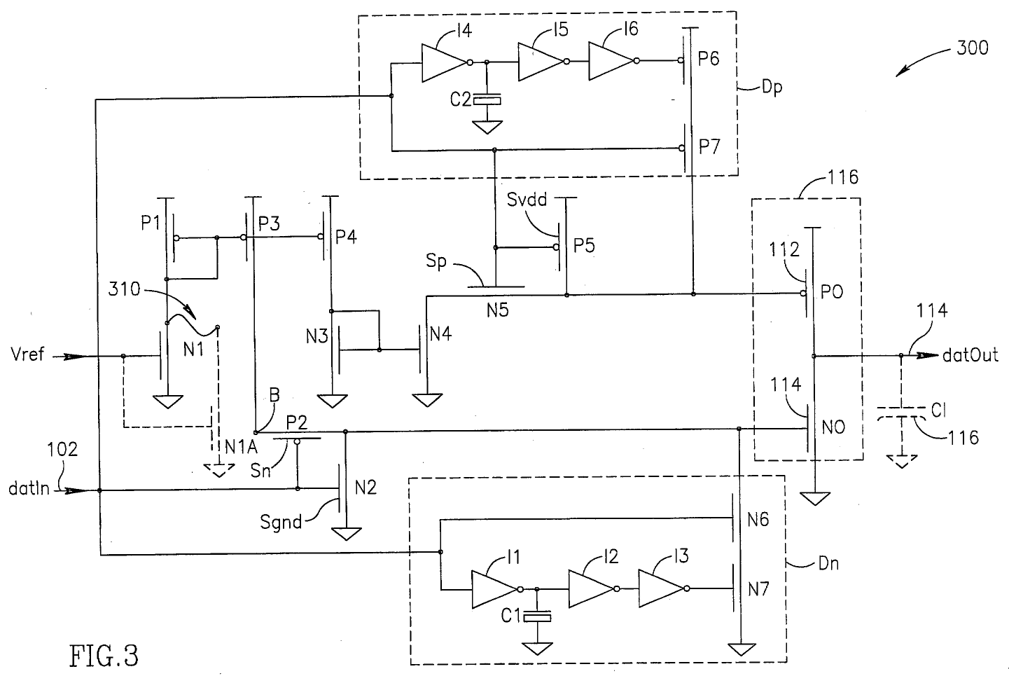

Reference is now made to FIG. 3, which illustrates a transistor circuit 300 that may be implemented in the output buffer 100, in accordance with an embodiment of the present invention. The circuit 300 may comprise a non-inverting output buffer that buffers signals from an input 102 to a load 106 connected to an output 104. A conventional pull-up and pull-down transistor pair 112, 114 may comprise an output stage 116. The pull-up transistor is preferably a PMOS device and is further denoted as transistor P0. The pull-down transistor is preferably an NMOS device and is further denoted as transistor N0.

The transistor circuit 300 may further include transistors in each of the pull-up and pull down paths (namely, transistors P5 and N2) to disable a respective transistor in the output stage 116. The transistors P5 and N2 correspond to the switches S_{VDD} and S_{GND} of FIG. 1. The data input 102 is connected to the gates of the transistors P5 and N2. Depending on the value of the signal at the data input 102, transistor P5 may be driven into conduction while transistor N2 may be open, or transistor P5 may be open and transistor N2 may be conducting. When transistor P5 is conducting, that is, when the data input is LOW, the voltage source VDD may pass through the drain of transistor P5 to the gate of output stage transistor P0, thereby clamping the output stage transistor 112 in a non-conductive state and isolating the data output 104 from VDD. Meanwhile, transistor N2 may be open and the gate of output stage transistor N0 may be driven so as to tie the data output 104 to ground potential. Conversely, when the data input is HIGH, transistor P5 may be open and the gate of output stage transistor P0 may be driven to tie the data output 104 to high potential. Meanwhile, transistor N2 may be conducting and the gate of output stage transistor NO may be grounded so as to isolate the data output 104 from ground potential.

The circuit of FIG. 3 may further include circuitry in each of the pull-up and pull-down paths to improve the disabling of the previously conducting path (pull-up or pull-down) before the other path (pull-down or pull-up, respectively) is enabled. The circuitry of FIG. 3, denoted D_{P} and D_{N}, may be used to enhance disabling, although other types of circuits may be used. By dividing the output switching into two phases, the disabling phase and then the enabling phase, the spike introduced to the supply and ground rails may be reduced as compared to that of a single-phase output switching cycle, where the disabling and the enabling occur in parallel.

When the input changes from high to low, in the pull-up path, the gate of the pull-up output transistor 112 may be driven high rapidly through the pull-up elements P7 and P6. Triggered by the same input transition, the pull-down output transistor 114 may turn on. The faster turn OFF of transistor 112 compared to the turn ON of transistor 114 to may minimize the Vdd to ground current conduction in the output stage 116, and thus minimize the switching noise. After a delay time determined for example by elements 14, 15 and 16, the pull-up path through P6 and P7 may turn off and the gate of the pull-up output transistor 112 may be maintained high by P5, being ready for the next low to high input transition. Similarly, when the input changes from low to high, in the pull-down path, the gate of the pull-down output transistor 114 may be driven low rapidly through the pull-down elements N7 and N6. Triggered by the same input transition, the pull-up output transistor 112 may turn on. The faster turn OFF of transistor 114 compared to the turn ON of transistor 112 may minimize the Vdd to ground current conduction-in the output stage 116, and thus minimize the switching noise. After a delay time determined for example by elements 11, 12 and 13, the pull-down path through N6 and N7 may turn off and the gate of the pull-down output transistor 114 may be maintained low by N2, being ready for the next high to low input transition.

The remaining transistors illustrated in FIG. 3 may cause a prescribed drive current to appear at the gates of the output stage transistors 112 and 114. The current source may be provided to cause the current in the output path to change at a constant rate during charging and discharging and thereby reduce or minimize switching noise.

Current may be sourced in the circuit of FIG. 3 by a transistor N1, which is preferably an NMOS device. The transistor N1 may be driven by a reference voltage V_{REF} and may provide a current on its drain line. A current mirror or amplifying circuit consisting of transistors P1, P3, P4, N3 and N4 may reflect or amplify the current from transistor N1. The current source N1 may comprise multiple transistors, such as N1 and N1A and may be trimmed to source a required amount of current by cutting (isolating) one or more transistors from the current mirror and amplifying circuitry. A large current source may enable the output stage to switch quickly, but may be subject to more noise than a smaller current source, which only allows the output stage to switch at a slower rate, but with less noise. The selection of speed and noise may be made at some stage of manufacturing by trimming the current source (e.g., using a laser to cut a fuse link 310 between one or more current source transistors).

The current source provided by transistor N1 may supply a constant current to the gate of the pull-up and pull-down transistors. This constant current may induce a gate voltage that rises linearly over time due to the capacitance at the gates of the pull-down transistor, as defined by the equation:

V_{gN}=(I_{oN}/C_{gN})·t

where V_{gN} is the voltage at the gate of the pull-down transistor, I_{ON} is the current that flows into the gate of the pull-down transistor, and C_{g} is the capacitance of the gate of the pull-down transistor, along with any parasitic capacitance or intentionally placed capacitance.

The equation for the pull-up transistor mirrors the above equation.

As mentioned before, for devices in velocity saturation mode, a gate voltage that varies linearly with time will cause the current in the output path to change linearly with a time during output charging and discharging operation.

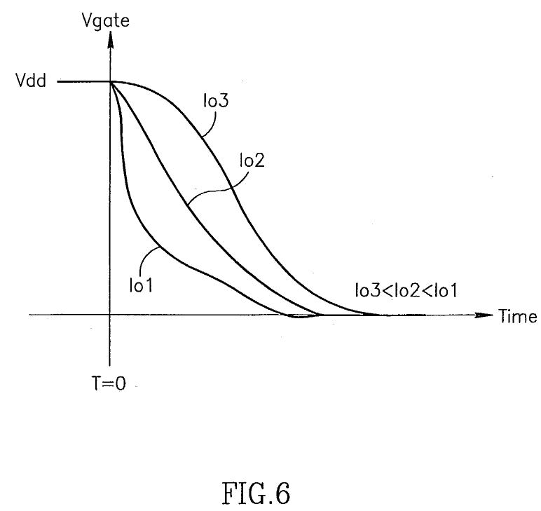

As may be appreciated from FIGS. 5-6, the speed of the output buffer is a function of the slope of the curve of the driving waveform of the output stage transistors 112 and 114. The slope of that curve varies directly with the size of the current source used to generate the waveform. The gate voltage is thus

V_{g}=(Iₒ/C_{g})·t

and varies linearly with time, with the slope of the curve being defined by the dimensions of the transistor (which may be prescribed by the need to handle large current) and also by the magnitude of the current source. FIG. 5 illustrates a family of curves that correspond to the selection of different current sources, in which Iₒ₁>Iₒ₂>iₒ₃. Each of the current sources may have a generally linear region that preferably extends throughout the operative period of the output buffer. FIG. 6 illustrates the speed of the output buffer with same W/L of the output pull-down transistor as a function of the magnitude of the current source driving the output pull-down transistor for output transitions from logic HIGH to logic LOW. In particular, the fastest switching is with current source Iₒ₁ and the slowest switching is with current source 103. It should be understood that transitions from logic LOW to logic HIGH may be plotted in an analogous manner.

Referring again to FIG. 3, transistor N5 serves as the switch S_{P} to provide a current to the gate of the output stage transistor 112, and transistor P2 serves as the switch S_{N} to provide a current to the gate of the output stage transistor 114. Because the operation of the two current mirror circuit paths may be the same, the following discussion concerns only the operation of the pull-down section for brevity.

At a time before the output line 104 transitions from HIGH to LOW, the gate of the output stage transistor 114 may be at low potential and the voltage at node B may be close to VDD. The size of transistors P2 and P3 is preferably chosen so that upon closure of transistor P2, a charge sharing effect results in a voltage at the gate of the transistor 114 (in accordance with the gate capacitance of transistor 114) which may be sufficient to place transistor 114 at or near its onset of conduction (V_{T}_{_{—}}_{N0}). This improves the output buffer speed without generating any noise, because the transistor does not conduct any significant current until its Vgs does not reach V_{T}_{_{—}}_{N0}.

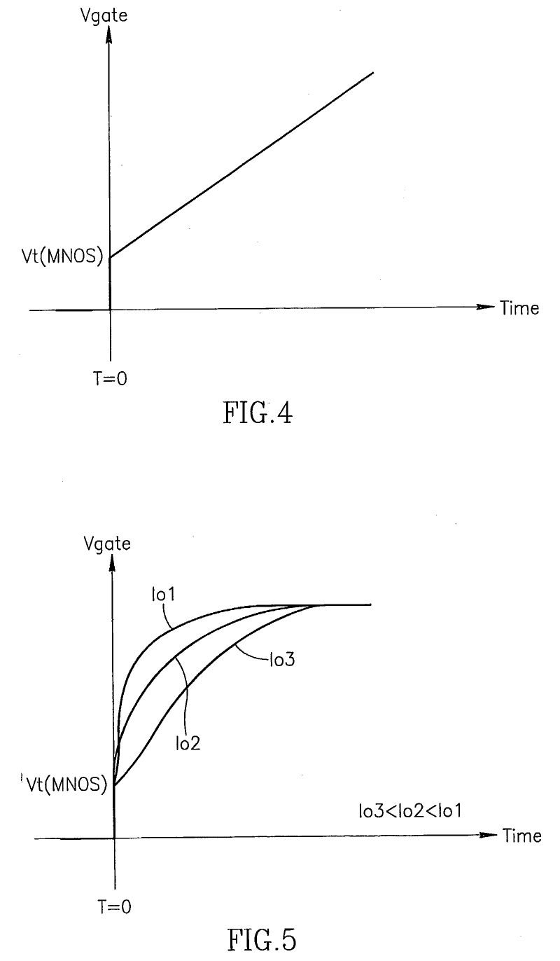

FIG. 4 illustrates a driving waveform for the transistor 114 which includes an initial waveform segment which may be configured to essentially instantaneously place the pull-down transistor 114 into conduction. The driving waveform has a second waveform segment that may be essentially linear over time. This second waveform segment may be developed by the continued application of the current source derived from transistor N1 through the current mirror and amplifying circuitry. The slope of the gate voltage waveform in FIG. 4 depends on the current flowing into the gate of transistor 114 and on transistor 114's gate capacitance. The slope may therefore be adjusted by changing the current source level. A larger transistor has the effect of reducing the slope of the gate voltage curve, but a dominant capacitor connected between the gate and drain terminals of the transistor may preserve a desired ramp rate if channel width or length is to be adjusted.

The term “connected” does not require a direct electrical connection between components. Rather, there may be intervening transistors and circuits to achieve other purposes, for example, to impose delays, to shield against electrostatic discharge, or for other reasons as understood by those of skill in the art. Connected is meant in its broad sense that one component or terminal thereof feeds another component downstream of that component or terminal.

Persons skilled in the art will appreciate that the present invention is not limited to what has been particularly shown and described hereinabove. Rather the scope of the present invention is defined only by the claims which follow.

What is claimed is:

1. An output buffer comprising:
at least one of a pull-up transistor and a pull-down transistor;
a waveform adapted to drive at least one of said pull-up transistor and pull-down transistor, comprising a first segment that brings said at least one of said pull-up transistor and pull-down transistor close to or at its turn-on condition substantially upon application of said waveform to a gate terminal of said transistor, and a second segment which in case of a pull-up transistor linearly decreases over an operative range, and in the case of a pull-down transistor linearly increases over an operative range.

2. The output buffer according to claim 1, wherein the first segment comprises a voltage which when applied to the gate of said transistor approximates the transistor gate-to-source voltage to its threshold voltage level.

3. The output buffer according to claim 1, wherein the second segment comprises a current source connected to the gate of said transistor.

4. The output buffer according to claim 1, wherein the second segment is linear over an operative range of the output buffer.

5. An output buffer comprising:
a path for either pulling-up a data output to logic HIGH or for pulling-down the data output to logic LOW, said path comprising:
a data input stage configured to receive a signal thereat;
an output stage transistor having a gate terminal;
a substantially constant current source; and
a switch responsive to the logic state of the signal received at the data input stage, the switch selectively connecting the substantially constant current source to the gate terminal of the output stage transistor, wherein the substantially constant current source applies a drive constant current to the gate terminal to convey the data output from the output stage transistor.

6. The output buffer according to claim 5, wherein the output stage transistor is in a velocity saturation mode.

7. The output buffer according to claim 5, wherein the substantially constant current source comprises a plurality of transistors and wherein the magnitude of the current source is trimmable.

8. The output buffer according to claim 5, wherein said switch of said data input stage, which connects the constant current source to the gate terminal of the output stage transistor, generates a waveform comprising:
a first short segment that brings said output stage transistor close to or at its turn-on condition substantially upon application to the gate of said output stage transistor; and
a second segment that linearly increases over an operative range.

9. The output buffer according to claim 8, wherein the second segment changes linearly with time.

10. The output buffer according to claim 8, wherein the second segment is linear over an operative range of the output buffer.

11. An output buffer comprising:
a data input configured to receive a signal thereat;
a data output configured to provide a logic value thereat as a function of the signal received at the data input;
a first signal path extending between the data input and the data output and selectively providing a logic HIGH to the data output, the first signal path including a first output stage transistor having a drain terminal connected to the data output and a gate terminal connected to a switch in the first signal path;
a second signal path extending between the data input and the data output and selectively providing a logic LOW to the data output, the second signal path including a second output stage transistor having a drain terminal connected to the data output and a gate terminal connected to a switch in the second signal path;
a constant current source available to supply current to each of the first and second signal paths; and
a switch in each of the first and second signal paths, the switch being responsive to the logic state of the signal received at the data input stage to selectively connect the constant current source to the gate terminal of a respective output stage transistor, wherein the current source applies a drive constant current to the gate terminal.

12. The output buffer according to claim 11, wherein the data output provides a logic value that is inverted relative to the signal received at the data input.

13. The output buffer according to claim 11, wherein the data output provides a logic value that is non-inverted relative to the signal received at the data input.

14. The output buffer according to claim 12, wherein said switch of said data input stage, which connects the constant current source to the gate terminal of the output stage transistor, generates a waveform comprising:
a first short segment that brings said output stage transistor close to or at its turn-on condition substantially upon application to the gate of said output stage transistor; and
a second segment that monotonically changes over an operative range.

15. The output buffer according to claim 14, wherein the first segment comprises a voltage which when applied to the gate of said output stage transistor approximates the threshold voltage level of said transistor.

16. The output buffer circuit according to claim 14, wherein the second segment changes linearly with time.

17. The output buffer circuit according to claim 14, wherein the second segment is linear over an operative range of the output buffer.

18. A method for driving an output buffer operating in a velocity saturation mode, comprising driving an output stage transistor with a constant current source.
